(19) United States
(12) Patent Application Publication
(10) Pub. No.: US 2002/0095688 A1
(43) Pub. Date: Jul. 18, 2002

(54) System and method of restoring cable service

(76) Inventor: Gerald M. Rich, New York, NY (US)

Correspondence Address: John P. Maldjian, Senior Patent and Trademark Counsel, TyCom (US) Inc., 250 Industrial Way West, Rm 2B-106, Eatontown, NJ, 07724, US

(21) Appl. No.: 09/764,588

(22) Filed: Jan. 17, 2001

(51) Int. Cl. H04N 7/173; H04L 1/22; H04B 1/74; H02H 3/05; H05K 10/00; H03K 19/003; H04N 7/16

(52) U.S. Cl. 725/116; 725/146; 714/6

(57) ABSTRACT

A method of operating a first cable system comprising relying on a dedicated back-up cable system for providing substantial restoration service to the first cable system.

### FIELD OF THE INVENTION

The present invention relates generally to the operation of cable systems. More specifically, the present invention relates to a system and method of providing restoration service to terrestrial and submarine cable systems.

### BACKGROUND OF THE INVENTION

A network of fiber-optic telecommunication cables links continents, nations, and lands together. Traffic on terrestrial and submarine cables has increased dramatically in recent years and is expected to grow as a result of many factors, including, for example, the globalization of world economies and businesses, the increased demand for international -communications capabilities, and the development of multimedia applications and revolutionary tools such as the Internet. Therefore, optimizing the operation of existing cables and investing in new, higher-capacity cables is a key objective.

This desire is complicated, however, by certain perils which often interrupt traffic or reduce capacity on the cables thus requiring them to be operated in such a manner as to maintain system integrity. The most common peril is external aggression which includes, for example, unauthorized digging, dredging or cutting of terrestrial cables; ships dragging anchors or fishing gear across the cables, environmental wearing of the cables through continuous contact with sharp or abrasive objects on the sea floor, and shark or other marine life interactions with submarine cables. Aside from external aggression, natural aggression, such as mud slides and earthquakes, and, to a lesser extent, component failure and planned maintenance can also cause traffic interruption.

Regardless of the cause, when a cable is rendered inoperative, traffic along the cable is interrupted and requires restoration. As used herein, the term “restoration service” refers to providing a user, operator, or owner of a cable system (collectively referred to hereinafter as an “operator”) with an alternative cable path such that, in the event transmission over the main or initial cable is interrupted, traffic may be rerouted to an alternative cable path. The term “restoring service” refers to the actual act of rerouting the traffic on the alternative path.

A restoration service plan typically addresses one or more of a cable system's basic components, namely: (1) a submarine cable or “wet plant” which is laid on, or partially buried in, the sea floor and which includes an extended digital line segment (DLS) between a cable landing site and the cable station; (2) cable landing stations into which the wet plant terminates and which contain the equipment necessary to transmit and receive the optical signals carried by the wet plant including optical-electrical converters and other apparatus, such as add/drop multiplexers (herein “ADMs”), digital cross connects, (herein “DXCs,”), and optical cross connects, (herein “OXCs,”); and (3) an inland facility or “back haul” which connects a cable landing station to a point of presence (POP) through a network of terrestrial lines. Considered specifically herein is restoration service of the wet plant, although the invention may be practiced to protect against failures of the cable station landings and/or back haul as well as terrestrial cable service.

Generally, there are two types of wet plant restorations—internal and external. In internal restoration, traffic is switched from one fiber within a given cable to another fiber within the same cable system or between cables within a ring system (discussed below). External restoration refers to the restoration of traffic on a completely different cable system or even on a terrestrial or satellite system. Of particular interest herein is restoring traffic by switching traffic between cables or cable systems. Accordingly, the term “restoration service” as used from this point forward refers specifically to switching traffic between cables or cable systems unless otherwise noted.

A recent approach for providing restoration service has been the implementation of ring systems. Ring cable systems comprise at least two cable segments that form a ring connecting two or more cable landing stations. The equipped capacity in each segment of a ring system is typically separated into working and protection capacity. The portion of a segment reserved for protection capacity typically comprises a number of independent fibers, thereby facilitating two types of protection—span switching and ring switching. Span switching affords the system protection against individual fiber or fiber pair problems or component failures (e.g. failed amplifiers) within a common cable while ring switching affords the system protection against external aggression or other types of catastrophic or complete failures (e.g., an incapacitated cable) that preclude span switching, by rerouting traffic around the cable/segment. Although a ring system provides a high degree of reliability, typically half of the equipped capacity of the system is nevertheless dedicated to protection capacity, thus diminishing the system's working capacity, and revenue generation.

In non-ring cable systems, and even in ring systems as an extra measure of reliability in the event of simultaneous segment failures which disable the ring switching capabilities, restoration service is provided under agreements among the various owners and operators of the cables. These types of agreements typically fall into three categories. The first category is “reservation restoration” in which a cable operator contracts for restoration service by reserving protection capacity on another cable system. The operator typically has the option of reserving primary and secondary restoration service. Primary restoration service tends to be more expensive than secondary restoration service and is used for non-preemptable telecommunication traffic while secondary service is used for preemptable traffic. “Preemptable” traffic is designated to be interrupted before “non-preemptable” traffic. Preemptable traffic typically is transmitted at a lower price rate than non-preemptable traffic, or it is restored traffic from another cable system. Both types may be preemptable to the internal or within system restoration requirements of the cable providing the restoration service.

The second category of restoration service among various cable operators is “mutual aid” in which various cable operators pool their resources to provide restoration service for the group. This approach typically works on a first-failed, first-served basis. The third category of restoration service is an ad hoc approach. As the name suggests, the ad hoc approach requires the operator of the interrupted cable to formulate a restoration plan at the time of interruption. Because there are no contracts in place at the time of interruption, there may be a chance that restoration service will not be secured with this last approach. Even if secured, restoration service tends to be more expensive than the first two approaches.

Regardless of whether the restoration services are provided through a ring cable configuration or through agreements among different cable operators, the fact remains that a certain portion of capacity needs to be dedicated to protection. Indeed, in ring systems, about 50% of the capacity is typically dedicated, and, in point-to-point cable systems, contractual obligations for providing restoration services and prudent operation tend to mandate that a significant portion, be reserved for protection. For example, if 1:1 span protection is required on a point-to-point system, 50% of the equipped capacity is reserved for protection.

Aside from the reduction in working capacity to provide for restoration service, point-to-point systems also lack certainty that service will be restored. More specifically, even with planned restoration, if more than one cable fails, more than likely some traffic will be preempted. Furthermore, it is generally acknowledged that restored traffic on a cable will be preempted if the host cable system needs the protective capacity for internal restoration. Therefore, under traditional (contractual) restoration service, there is typically no guarantee that service will be restored.

Therefore, there is a need for a restoration approach that avoids reserving a significant portion of the equipped capacity for protection, and that provides a greater measure of certainty that traffic will be restored.

### SUMMARY OF THE INVENTION

The present invention provides a restoration approach that facilitates increased transmission over new and existing cables by using a dedicated back-up cable or cable system for restoration services, thereby eliminating the need for reserving protection capacity on such cables. It is appreciated that the intermittent need for restoration service and the low probability that more than one cable will need restoration at any given time equates to a collective need of less than full restoration for all cables at any given time. Accordingly, the collective need is pooled into a small number of back-up cable systems (either ring systems or point-to-point systems) dedicated for restoration service of multiple cables. By pooling the need for restoration service into one or just a few cable systems, protection capacity in the other cable systems is made available up for working capacity/non-preemptable traffic, thereby increasing the flow of traffic/revenue on these systems. The present invention also reduces the capital expenditure of new cable systems by eliminating the need for restoration service of ring cable systems. For example, the need for a Bi-directional Line Switched Ring (BLSR), or Multiplexer Section Shared Protection Ring (MSSPRing) needed by ring systems would be obviated. That is, even though the system may physically look like a ring, it would not require ring switching or even span switching capabilities, because protection would be provided via the dedicated backup system. Therefore, operators no longer need to build rings for purpose of protection, but only for traffic demand, connectivity, or political purposes. Both point-to-point and ring systems would be able to use a greater portion of their equipped capacity for working capacity, perhaps even as much as 100%.

A dedicated backup cable system also allows cable operators to subscribe to the level of restoration service they desire. For example, an operator may subscribe to a non-preemptable service and know that, regardless of other cable system failures, service will be provided. This confidence in restoration service is due to the fact that the primary responsibility of a dedicated backup cable system is to its subscribers, and not to its own traffic. The dedicated back-up cable system of the present invention also encourages the backup cable to be constructed of premium materials/components and to employ state-of-the-art engineering/design principles and technology to increase its reliability and capacity. For example, to reduce external aggression, it may be preferable to bury the cable deeper in the ground or the ocean floor or to run part or all of it through existing tunnels or over land. To increase capacity, the cable may employ advanced transmission techniques such as Internet Protocol (IP). Future capacity upgrades also could be supported by reducing distance between undersea amplifiers/repeaters or the use of other techniques/technologies, which would allow for higher transmission rates, thus offsetting the cost of additional repeaters.

Accordingly, one aspect of the invention is a method of operating a cable by relying on a dedicated back-up cable for providing substantial restoration service of the cable.

Another aspect of the invention is a method for providing restoration service by providing substantial restoration service to two or more cables on a dedicated backup cable.

Yet another aspect of the present invention is a system for providing restoration service to two or more subscriber cable systems. In a preferred embodiment, the dedicated backup cable system comprises: (a) at least one dedicated backup cable system; and (b) an interface between the backup cable system and the subscriber cable systems such that if transmission over one or more of the subscriber cable systems is interrupted, traffic is transferrable to the backup cable.

### BRIEF DESCRIPTION OF DRAWINGS

The invention may best be understood by reference to the following description taken in conjunction with the accompanying drawings, wherein like reference numerals identify like elements, and wherein:

FIG. 1 shows a network of submarine cables with a dedicated back-up cable system of the present invention; and

FIG. 2 shows a network of submarine cables including a dedicated back-up cable of the present invention all using common cable landing stations.

### DETAILED DESCRIPTION OF THE PREFERRED EMBODIMENT

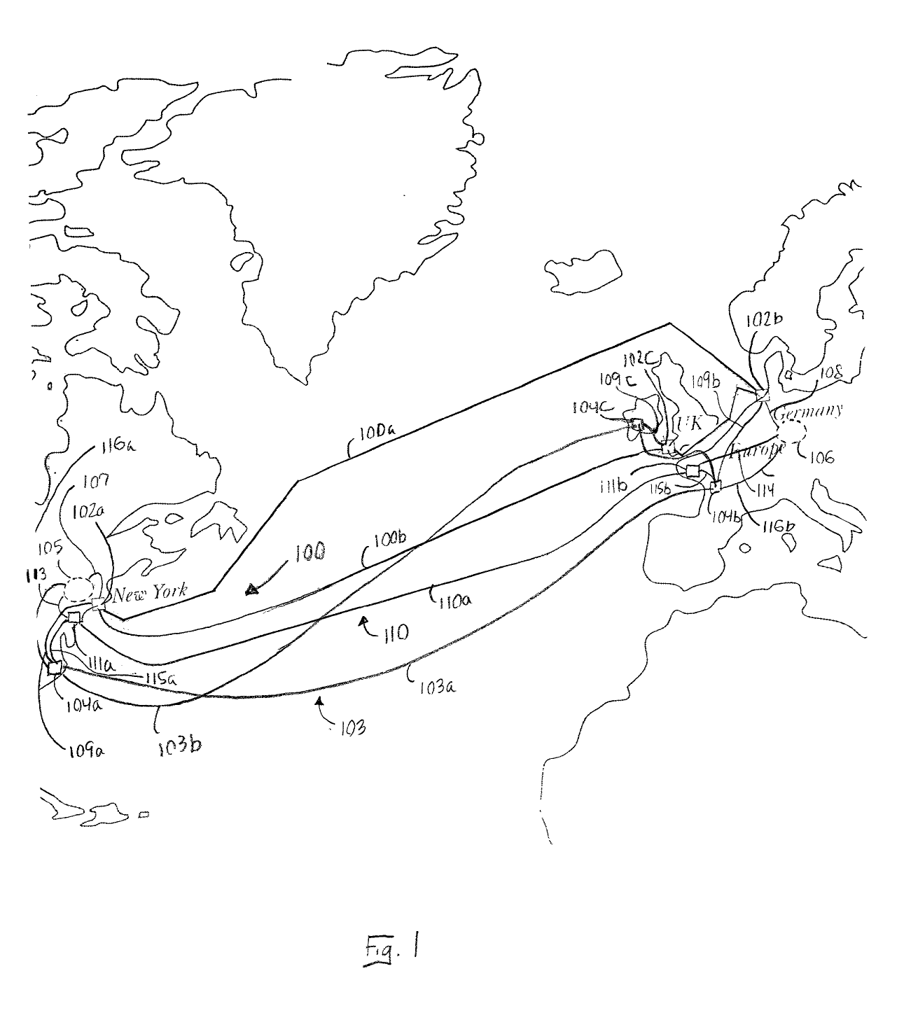

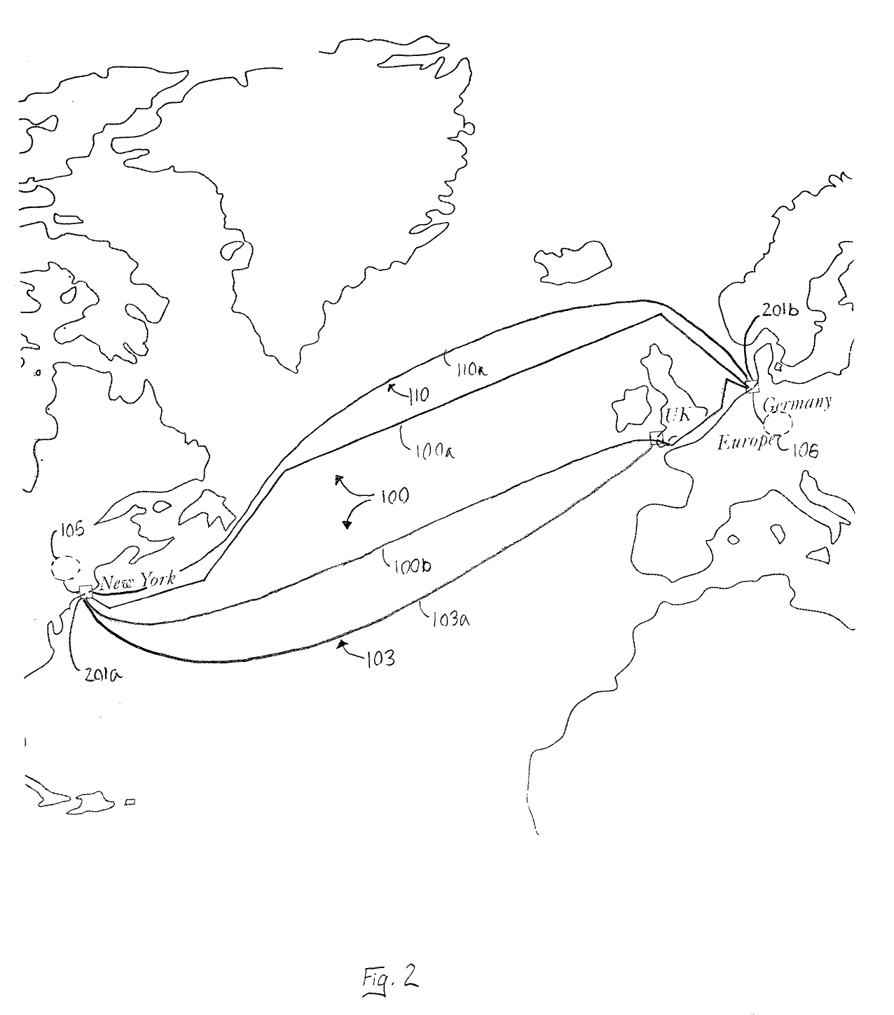

Referring to FIGS. 1 and 2, preferred embodiments of the present invention are shown. In FIG. 1, a network of submarine cables and their associated infrastructure is schematically shown. More specifically, a conventional ring system 100 is shown with a wet plant comprising cables 100a and 100b terminating in the cable landing stations 102a, 102b and 102c. Although just one cable landing station is depicted in each country, a common form of Transatlantic ring would have two cable landing stations in the US/Canada and two in the UK/Europe. These cable landing stations in turn are connected to a point of presence (POP) 105 and POP 106 via the back haul or terrestrial line 107 and 108, respectively. A point-to-point cable system 110 is also depicted. Cable system 110 comprises a wet plant, cable 110a, which spans from cable landing station 111a to cable landing station 111b, each cable landing station, in turn, being connected to POPs 105 and 106 via terrestrial lines 113 and 114, respectively. It should be recognized that ring cable system 100 and point-to-point cable system 110 depicted in FIG. 1 are conventional cable systems well known in the art.

The network of cable systems depicted in FIG. 1 is enhanced by a back-up cable system 103. Back-up cable system 103 comprises a ring configuration of dedicated back-up cables 103a and 103b connected to cable landing stations 104a, 104b and 104c. As used herein, the term “dedicated backup cable system” refers to a cable system in which a majority portion of its equipped capacity is reserved for restoration services. A ring system is depicted and is generally preferred given its high reliability compared to point-to-point cable system, although the present invention may be practiced with a point-to-point cable system, several point-to-point systems, multiple ring systems, or even a combination of point-to-point and ring system(s). Additionally, although not considered specifically herein, the present invention may be practiced with a “mesh” system which is a new type of cable system being contemplated by the industry. Finally, this configuration may be used in a terrestrial systems, with certain modifications necessary for land-based networks.

In a preferred embodiment, at least about 60% of the equipped capacity of the backup cable system is reserved for restoration services, in a more preferred embodiment, at least about 80% of the equipped capacity is reserved for restoration service, and, in an even more preferred embodiment, substantially all of the equipped capacity is reserved for restoration service. Reserving such equipped capacity for restoration service means that such capacity cannot be used to transmit full time service. In other words, when the dedicated backup cable is in standby mode (i.e., it is not restoring service for another cable), the reserved capacity transmits no traffic or only preemptable/part-time (temporary) traffic such that such capacity is immediately available for restoration services.

The dedicated backup cable may be any conventional cable, although because the cable is used as a backup cable, it may be preferable to take certain measures in its design and installation to ensure a higher degree of reliability than is traditionally imparted into conventional cables. For example, it may be preferable to bury a greater portion of the backup cable, bury it deeper or dump more rocks on the cable to protect it when burial is not possible than is traditionally done, or use conduits or other means to protect it. Furthermore. where appropriate, it may be beneficial to run the cable through existing tunnels where reliability is virtually assured even though the fee to use the tunnel may be high. For example, the tunnel between England and France (termed the “Chunnel”) may be used to run a cable across the English Channel where external aggression tends to be a problem. Additionally, to improve reliability, the dedicated backup cable systems may employ a ring system approach (utilizing both span and ring protection switching). It is also contemplated that mesh protection could be incorporated into the dedicated backup cable. By making the backup cable system highly reliable, the cable systems it supports may be installed with slightly relaxed standards to reduce installation or initial cost.

In addition to making the cable system exceptionally reliable, it may be beneficial to incorporate state-of-the-art technology to handle current capacity from some of the more recent cables and to afford the cable the best opportunity to handle the higher capacities as more technologically-advanced cables are installed. To this end, it may be preferable to adopt Internet Protocol (IP) as the standard for transmitting traffic over the cable. Additionally, in anticipation of the need to increase the transmission rate (e.g., from 10 Gb/s to 40 Gb/s), or to support future higher quantities of dense wavelength division multiplexing (DWDM) wavelengths, it may be desirable to increase the number of repeaters/amplifiers in the cable.

Backup system 103 also comprises interfaces 109a and 115a, 109b and 115b, and 109c between the backup cable 103a and cable systems 100 and 110 such that if transmission over one or more of the cables 100a, 100b or 110a is interrupted, traffic is transferrable to the backup cable. The interface of the embodiment shown in FIG. 1 comprises a back haul component which may have several configurations. In one embodiment, the cable landing stations 104a, 104b, and 104c of the backup system interconnect to the landing stations 102a, 102b, and 102c of the ring system 100 via telecommunication lines 109a, 109b, and 109c, respectively, and to the cable stations 111a and 111b of the point-to-point system 110 via telecommunication lines 115a and 115b, respectively. Such interfaces may be owned or leased by the operators of the backup system.

In another embodiment, rather than interconnecting the various cable systems through the cable landing stations, the back-up system 103 of the present invention may connect directly with POPs 105 and/or 106 via telecommunication lines 116a and 116b. When the back-up cable system is connected to cable landing stations, the restoration service would most likely be provided to the owners of cable systems 100 and 110. However, when the back-up cable system is connected to the POPs, it is likely that the restoration service would be provided to the cable systems' customers. Hence, their traffic would be restored regardless of which cable system they were using. It is contemplated that customers could choose a combination of cable station and POP-based restoration.

In a preferred embodiment, the interface comprises an optical cross connect for interconnecting the optical fibers between the various cable systems. The concept of cross-connects is well-known, and has been used in digital cross connects (e.g., Lucent Technology's DACS product line). “Optical” cross connects (OXCs) are a more recent innovation. Many “optical cross connects” still utilize optical to electrical to optical conversions and perform most of the cross connections in the electrical domain, although purely optical OXCs are beginning to appear. The optical cross connects may be implemented in different ways. For example, in a centralized design, one large OXC may be installed in the back-up system's cable landing station by bringing fibers in from the other systems' cable landing stations. Alternatively, in a distributed design small OXCs may be installed in each of the subscriber cable landing stations, as well as in the back-up systems cable landing station.

FIG. 2 shows an alternative embodiment of the present invention in which the interface between the backup system 103 and the cables systems 100, 110 comprises common cable stations 201a, 201b. Common cable stations may be used to operate a plurality of cables, even those owned by different entities. By having common cable landing stations operate the back-up cable 103a along with the cables 100a, 100b, and 110a, the telecommunication links between the various cable landing stations can be eliminated. Accordingly, switching between the back-up system and the cables can be performed within a common cable landing station. Common cable landing stations eliminate duplication of hardware and infrastructure in multiple cable landing stations and the back haul which supports individual cables or cable ring systems. They also minimize delays and the expense in establishing added links in the restoration path, although the dedicated equipment to connect the systems is still needed. Although only one back haul is depicted in FIG. 2, it should be understood that a second back haul route from the shared cable station to the POP may be preferable to increase reliability.

Using the backup system illustrated in FIGS. 1 and 2, a method is provided for operating the submarine cable systems 100 and 110. The shared protection facility provides restoration for not only cables 100a, 110b, and 110a, but also for some terrestrial components (i.e., back haul) of these cable systems, especially when restoration is performed at the POPs. As used herein, the term “substantial restoration service” refers to an anticipated restoration of at least about 50% of the full-time traffic on a particular cable. In a preferred embodiment, the dedicated backup cable provides for the restoration of at least about 75% of the full-time traffic on the cable, and, in an even more preferred embodiment, the dedicated backup cable system provides for substantially all of the full-time traffic on the particular cable.

By shouldering the responsibility for providing restoration service to a multitude of cables, cables are free to operate more efficiently. More specifically, cables 100a, 100b and 110a need not reserve protection capacity, and instead may utilize a greater portion of their equipped capacity as working capacity. In other words, a significant portion of a cable's equipped capacity may now be utilized as working capacity without regard to having the capability to restore enough capacity to provide substantial restoration service. Because there is no need to provide restorative services, a cable segment of a ring system can use more than 50% of its equipped capacity as working capacity. In a preferred embodiment, a cable is operated such that at least 60% of its equipped capacity is used as working capacity, and, even more preferably, at least 80% is used as working capacity. In an even more preferred embodiment, substantially all of the equipped capacity is working capacity.

The dedicated backup cable system not only provides for higher operating efficiency, but also reduces operational and capital costs. More specifically, because the collective need for restoration is pooled, more efficient use of restoration service is realized, thereby eliminating the need to design protective capacity into systems. For example, even if a PTP cable system operator chooses to provide 1:1 span protection on its cable where one fiber (or wavelength) provides protection for 1 fiber (or wavelength) and relies only on the cable backup system for a cable failure (thereby requiring it to dedicate 50% of its equipped transmission capacity to protection), the dedicated back-up system would still benefit the cable system operator financially. This is true because the need and associated risks for additional capital outlays for the construction of a second Transatlantic cable to form a ring system would be obviated. Thus, by making restoration service on a dedicated backup cable available, the need to install a ring system, i.e., a second cable, is obviated, thus, significantly reducing the cost and maintenance of a new cable system. Alternatively, as described above, the cable system owner may install a ring anyway but without ring protection capabilities, and perhaps without dedicating fibers (or wavelengths) for protection.

The cost of using a dedicated backup system is less than installing a second cable to form a ring system because the dedicated backup cable services a plurality of cable systems. As mentioned above, the dedicated backup cable services multiple cables by exploiting the low probability that the subscribers will need restoration service at the same time. Preferably, the cost of subscribing to the dedicated backup cable is a fraction of the cost of a second cable to form a ring system over the life of the cable system.

The fee structure for subscribing to a dedicated backup system may vary according to the needs and expectations of the subscriber. For example, restoration service may be planned and contracted in anticipation of need. Such planned restoration services may be tiered depending upon the level of restoration service desired. For example, primary or premium service may entail reserving certain fibers or transmission wavelengths for a subscriber wherein these fibers/wavelengths always would be available to the subscriber even 11f other cable systems required restoration. Alternatively, a premium service subscriber may be assured a certain portion of the backup cable's capacity regardless of other system failures. In either of the above cases, the subscriber might allow their “dedicated” capacity to be used by another subscriber, as long as it did not need the capacity itself. This could be offered as another tier of service. Secondary or economy service may entail only rights to a pro rata distribution of the available capacity of the dedicated backup cable if more than one cable system requires restoration. By offering tiered service, a subscriber can assure its restoration service regardless of the condition of other cables. Furthermore, subscribers may choose to purchase restoration capacity at more than one tier, for example, choosing premier service for 50% of their capacity requirements and economy service (or none at all) for the remaining 50%.

Fees for restoration service may be paid on a periodic basis, for example, as an annual or as an up-front, lump sum. It is anticipated that periodic payments will probably be preferred so as to defer costs as much as possible and make subscribing to the dedicated backup cable particularly attractive. Alternatively, restoration service on the dedicated-backup system may be traded for working capacity on an operator's system (or something else they have). As used herein, the term fee refers broadly to money, or service or goods in trade.

Aside from reserved restoration service, restoration service on the dedicated backup cable may be provided on an individual or ad-hoc basis. Under these circumstances, a cable operator (or their customer) who has suffered an interruption in traffic transmission, contracts in real-time to use the dedicated backup cable, preferably at a rate that exceeds that paid by subscribers of reserved restoration. In a preferred embodiment, the fees paid for emergency restoration service are at least 25% more than those paid by subscribers. Furthermore, in the event a subscriber requires restoration service and there is insufficient capacity to support the subscriber and another cable on an individual or ad-hoc basis, it is anticipated that the restoration service provided on the individual or ad-hoc basis would be preempted. As described above, subscribers may choose to reserve protection capacity (premium or economy) for only a portion of their needs. When necessary, they could contract for individual or ad hoc services for the remainder of their needs.

In addition to providing restoration service, it is anticipated that the dedicated backup cable may be used to provide temporary additional capacity for a cable system. More specifically, in the event a cable operator needs additional capacity to accommodate its traffic, for example, during a world event that leads to increased telecommunication or even while the operator is awaiting the installation of additional capacity (or the initial activation of capacity), capacity on the dedicated backup cable may be available for lease. In a preferred embodiment, such use would be subject to preemption and offered at a premium price.

Rather than subscribing to the dedicated backup cable, it may be preferred under certain circumstances for the cable operators to invest jointly and become joint owners of the dedicated backup cable. This approach also exploits the low probability that the member cable systems will need restoration service at the same time. Because the dedicated backup cable would be owned by more than one cable operator, the costs of installing and maintaining it would be dispersed. In essence, various cable operators would be timesharing the dedicated backup cable with the unusual circumstance that they typically would not know when they would need to use it. Part ownership in the dedicated backup cable could also be tiered like the premium and economy subscriber services described above such that part owners having non-preemptable rights to certain fibers/wavelengths or a percentage of the equipped capacity would pay more. Another embodiment of this approach involves the restoration provider installing a cable and selling a portion of it to other cable operators. They might buy a portion equal to their needs, or they might buy a larger portion (and thus share in revenues from other operators), or a smaller portion whereby they would also need to contract for additional capacity just like any other customer (perhaps with a discount). The discussions above about bartering and/or allowing others to utilize their reserved capacity when they do not require it themselves is also applicable here.

As an alternative to providing restoration service on a dedicated backup cable system to cable system operators, it may be preferred to offer such services at the POP to the retail telecommunication carriers or directly to the carrier's customers despite the additional effort to engineer, test, contract and operate individual STM-ls and other low speed signals. Such an approach has the advantage of dealing directly with the carriers and avoiding the cable operator as a middleman. Additionally, by providing restoration services right to the POP, the dedicated backup cable system of the present invention can accommodate failures not only along the undersea cable of a cable system, but also at the cable landing station and/or back haul.

What is claimed is:

1. A method of operating a first cable system comprising:
relying on a dedicated back-up cable system for providing substantial restoration service to said first cable system.

2. The method of claim 1, wherein an operator of said first cable system pays a fee or equivalent worth for restoration service on said dedicated backup cable system.

3. The method of claim 2, wherein said fee is less than the difference between the capital expenditure of said first cable system being a point-to-point (PTP) cable system and said first cable systems being a ring cable system.

4. The method of claim 1, further comprising:
operating said first cable system such that its protection capacity is not suitable for providing substantial restoration service to itself or to a second cable system.

5. The method of claim 4, wherein said first and second cable systems are part of a ring cable system and said dedicated back-up cable system is not part of said ring cable system.

6. The method of claim 5, wherein over about 50% of the equipped capacity of said first cable system is working capacity.

7. The method of claim 6, wherein over about 60% of the equipped capacity of said first cable system is working capacity.

8. The method of claim 7, wherein over about 80% of the equipped capacity of said first cable system is working capacity.

9. The method of claim 8, wherein substantially all of the equipped capacity of said first cable system is working capacity.

10. The method of claim 1, wherein said dedicated backup cable system is owned by a plurality of cable system operators who rely on said backup cable system for restoration service.

11. A method of providing restoration service comprising: providing substantial restoration service for two or more cable systems on a dedicated backup cable system.

12. The method of claim 11, wherein said restoration service is provided to an operator of one of said cable systems.

13. The method of claim 11, wherein said restoration service is provided at a POP.

14. The method of claim 11, further comprising: transmitting more preemptable traffic than non-preemptable traffic when said back-up cable system is not restoring service to one or more of said cable systems.

15. The method of claim 11, wherein said restoration service is provided for a periodic fee from an operator of one of said cable systems.

16. The method of claim 15, wherein the total of periodic payments is less the difference between the capital expenditure of said one of said cable systems being a PTP cable system and said one of said cable systems being a ring cable system.

17. The method of claim 16, wherein said total is less than about half of said difference.

18. The method of claim 11, wherein said restoration service is provided under a contract of planned restoration.

19. The method of claim 18, wherein restoration service is tiered.

20. The method of claim 19, wherein said tiered service comprises premium service, wherein either certain fibers or wavelengths or a portion of the equipped capacity are reserved, and economy service wherein capacity is distributed evenly among operators.

21. The method of claim 18, wherein said restoration service is provided on an individual or ad hoc basis at a fee greater than that charged under said contract.

22. The method of claim 11, wherein traffic is transmitted over said backup cable system using IP.

23. The method of claim 11, wherein said backup cable system is owned by two or more cable system operators.

24. The method of claim 11, further comprising:
transferring traffic from one of said cable systems to said dedicated back-up cable system when transmission over said one cable system is interrupted.

25. The method of claim 24, further comprising:
transferring traffic back to said one of said cable systems from said dedicated back-up cable system when transmission over said one cable system is restored.

26. The method of claim 11, further comprising:
leasing capacity on said back-up cable system other than restoration service to a cable system operator on a temporary basis.

27. A system for providing restoration service to two or more cable systems comprising:
a dedicated backup cable system comprising at least a cable; and
an interface between said backup cable system and said cable systems such that if transmission over one or more of said cable systems is interrupted, traffic is transferrable to said backup cable system.

28. The system of claim 27, wherein a portion of the cable of said dedicated backup cable system passes through a tunnel.

29. The system of claim 27, wherein a portion of the cable of said dedicated backup cable system passes over terrestrial facilities.

30. The system of claim 27, wherein said dedicated backup cable system is operated by a shared cable station which services cable systems for which said backup cable system provides restoration service.

31. The system of claim 27, wherein said interface comprises a telecommunication link between a cable landing station of at least one of said cable systems and a cable landing station of said dedicated backup cable system.

32. The system of claim 27, wherein said interface comprises an optical cross connect connecting said dedicated backup cable system with at least one of said cable systems.

33. The system of claim 27, wherein said interface comprises a telecommunication link between a POP and a cable landing station of said dedicated backup cable system.
